(19) United States
(12) Patent Application Publication
(10) Pub. No.: US 2008/0311686 A1
(43) Pub. Date: Dec. 18, 2008

(54) Method of Forming Semiconductor Layers on Handle Substrates

(75) Inventors: Anna Fontcuberta i Morral, Garching (DE); Sean M. Olson, Pasadena, CA (US)

Correspondence Address: Hiscock & Barclay, LLP, One Park Place, 300 South State Street, Syracuse, NY, 13202-2078, US

(73) Assignee: California Institute of Technology

(21) Appl. No.: 11/997,640

(22) PCT Filed: Aug. 2, 2006
(86) PCT No.: PCT/US06/30374

§ 371 Date: Jul. 2, 2008

Related U.S. Application Data
(60) Provisional application No. 60/705,619, filed on Aug. 3, 2005.
(60) Provisional application No. 60/705,172, filed on Aug. 4, 2005.

(51) Int. Cl. H01L 21/265; H01L 21/66

(52) U.S. Cl. 438/7; 438/455; 438/518; 257/E21.34; 257/E21.525

(57) ABSTRACT

A method of making a semiconductor thin film bonded to a handle substrate includes implanting a semiconductor substrate with a light ion species while cooling the semiconductor substrate, bonding the implanted semiconductor substrate to the handle substrate to form a bonded structure, and annealing the bonded structure, such that the semiconductor thin film is transferred from the semiconductor substrate to the handle substrate.

### CROSS-REFERENCE TO RELATED PATENT APPLICATIONS

The present application claims benefit of priority of U.S. provisional applications Ser. Nos. 60/705,172 filed on Aug. 4, 2005 and 60/705,619 filed on Aug. 3, 2005 all of which are incorporated herein by reference in their entirety.

### FIELD OF THE INVENTION

The invention relates to semiconductor fabrication and specifically to methods of forming exfoliated semiconductor layers on foreign handle substrates.

### BACKGROUND OF THE INVENTION

InP and GaAs form the basis for the fabrication of a number of high performance devices by epitaxial growth of InP-lattice-matched materials. Examples of devices are lasers in the communication wavelengths (1.5 and 1.3 μm) such as edge emitting lasers vertical cavity surface emitting lasers (VCSELs), and a variety of high speed electronic devices such as heterojunction bipolar transistors (HBTs) and other devices such as high efficiency solar cells. However, commercial implementation of many of these devices is limited due to the lack of a readily available, low cost, and lattice-matched substrate material for InP-lattice-matched and related compound semiconductors such as GaAs.

### SUMMARY

A method of making a semiconductor thin film bonded to a handle substrate includes implanting a semiconductor substrate with a light ion species while cooling the semiconductor substrate, bonding the implanted semiconductor substrate to the handle substrate to form a bonded structure, and annealing the bonded structure, such that the semiconductor thin film is transferred from the semiconductor substrate to the handle substrate.

### BRIEF DESCRIPTION OF THE DRAWINGS

FIG. 1 is a side cross sectional view of ion implantation with a light gas ions 10 of a substrate 1 to generate a subsurface damage layer and light atom reservoir 2. As used herein, light ions include H⁺, H₂⁺ and/or He⁺.

FIGS. 2A-F are optical micrographs and Atomic Force Microscopy (AFM) micrographs of various surfaces. FIGS. 2A and 2B are optical and AFM micrographs, respectively, of an InP surface that has not suffered any transformation after implantation and annealing. FIGS. 2C and 2D, are optical and AFM micrographs, respectively, of an InP surface showing the formation of bubbles due to the accumulation of the implanted gas underneath the surface. FIG. 2E is an optical micrograph of an InP surface showing blisters after implantation and annealing. FIG. 2D is an optical micrograph of an InP wafer showing complete exfoliation of a surface layer after implantation and annealing.

FIG. 3 is a transmission FTIR spectra around 1600 cm⁻¹ corresponding to In-H. The spectrum on the bottom corresponds to as implanted InP and the rest to the same InP annealed at different temperatures for 10 minutes. Spectra are displayed vertically for purposes of comparison.

FIG. 4 is a transmission FTIR spectra around the region where P-H modes absorb. The bottom spectrum corresponds to implanted InP and the rest to the same InP annealed at different temperatures for 10 minutes. Spectra displayed vertically for comparison purposes.

FIG. 5 is a plot of the percent of hydrogen evolved as a function of temperature deduced from FTIR and hydrogen evolution measurements.

FIG. 6A is a schematic illustration of the notation of the parallel and perpendicular components of electrical field of the radiation incident to a prism.

FIG. 6B is a plot of normalized intensity of the field components as a function of the distance to the surface, overlapped with the hydrogen profile in InP after current implantation.

FIG. 7 illustrates Multiple Internal Transmission FTIR spectra of hydrogen implanted InP as implanted and after 10 min isochronal annealing at 172, 294 and 352° C., for two light polarizations: polarization s (FIG. 7A) and polarization p (FIG. 7B). Spectra are displayed vertically for purposes of comparison

FIGS. 8A-8E are schematics illustrations of five different P—H bond configurations corresponding to the stretching modes of H in InP. FIGS. 8A, 8B and 8C correspond to defect configurations (modes at 2060 cm⁻¹, 2198 cm⁻¹ and 2217-27 cm⁻¹).

FIGS. 8D and 8E correspond to stretching vibrations of mono and di-hydrides on the (100) InP plane (modes at 2268-75 cm⁻¹ and 2308-10 cm⁻¹).

FIG. 9 is a plot of secondary ion mass spectroscopy (SIMS) concentration profiles in InP for different wafer types (as implanted and after annealed at 340° C. for 30 min), illustrating the difference in hydrogenation for different kinds of wafers. The profiles also show that, in cases where the InP is not able to blister or exfoliate, hydrogen stays trapped in the material after annealing.

FIG. 10 is a plot of secondary ion mass spectroscopy concentration profiles in InP for two different implant processes (as implanted and after being annealed at 340° C. for 30 min), illustrating that for the same total dose, the concentration of hydrogen in the material is superior when the material is kept at a temperature below 50° C. during implantation.

FIG. 11 is a plot of secondary ion mass spectroscopy helium concentration profile in InP for a substrate implanted with a total dose of 1.25×10¹⁷He⁺/cm² at 115 keV and wafer temperature below 150° C. The wafer was mounted on an air-cooled platen and successfully exfoliated when heated up to 300° C.

FIGS. 12A and 12B are plots estimations of the coefficient of diffusion of hydrogen and out-diffusion time, respectively, in InP as a function of temperature, as deduced from hydrogen evolution experiments.

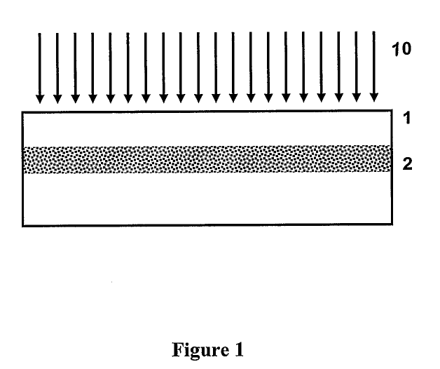

### DESCRIPTION OF THE EMBODIMENTS OF THE INVENTION

The embodiments of the invention provide methods for ion implantation induced exfoliation of InP, GaAs and related materials. The methods can be used for layer transfer of the exfoliated thin film onto a foreign handle substrate by wafer bonding techniques to form a new substrate comprising of a thin transferred III-V semiconductor film integrated with a foreign handle substrate to combine the III-V material with the desirable material properties of the handle substrate, such as mechanical toughness and thermal conductivity.

The methods provide preferred implant conditions and material combinations that enable layer transfer and optimize the performance of the layer transfer method. The substrate temperature during implantation, current and ion doses can be controlled to optimize the layer transfer. The desired substrate temperature during implantation is deduced from hydrogen thermal evolution during exfoliation and secondary ion mass spectroscopy (SIMS) measurements taken before and after annealing. An explanation of the layer exfoliation mechanism and its study via Fourier Transform infrared (FTIR) spectroscopy is presented. The FTIR spectroscopy technique allows the determination of the hydrogen configurations that lead into hydrogen induced exfoliation, which can be used for quality control of the implanted wafers, for optimization or control of implantation conditions during implantation of subsequent wafers, as well as for in situ monitoring of exfoliation during layer transfer.

Wafer bonding and layer transfer of semiconductor films or layers, such as InP and GaAs films, presents a way to enable InP- and GaAs-based technology by reducing the substrate cost, while adding the functionality of the handle substrate. For example, InP or GaAs transferred films on silicon handle substrates have the potential of integrating the optical and electronic capabilities of III-V semiconductors with Si microelectronics. Any other handle substrates other than silicon, such as other semiconductor materials or glass or plastic materials, for example, may be used as long as the handle substrate material is different from the transferred film material. Additionally, the use of wafer bonding and tailored substrates opens up possibilities for integrating InP with materials for which heteroepitaxy is not possible, such as amorphous films or substrates and low-cost polycrystalline substrates tailored to improve the optical and thermal properties of the finished device. The terms “layer” and “film” are used interchangeably herein. Furthermore, a bonding layer or layers may be used to bond the handle substrate to the transferred film.

The use of ion implantation to exfoliate thin films of InP and GaAs is physically restricted to a material-specific implantation process parameter space. This parameter space is a consequence of the physical properties of these III-V semiconductors, specifically the values of diffusion coefficient of the implanted species at the implantation temperatures and the crystalline structure at the nano-scale determined by the crystal pulling method.

Multiple methods and conditions for repeatable hydrogen ion implantation of InP and GaAs for transfer of films of these materials to handle substrates are described below. The methods are also applicable to InP and GaAs alloy materials, such as GaInP and InGaAs, for example, as well as to other related III-V materials such as InN, GaP, as well as ternary or quaternary alloys comprised of In, Ga, P, N, and As.

The described methods, in combination with wafer bonding, enable layer transfer of InP and other semiconductor films onto foreign handle substrates. The mechanism underlying ion induced layer exfoliation, which allows good control of the technique, is also described. Additionally, instead of hydrogen implantation, helium or hydrogen plus helium implantation may be used induce exfoliation in these materials.

### Nomenclature of Ion Induced Layer Exfoliation

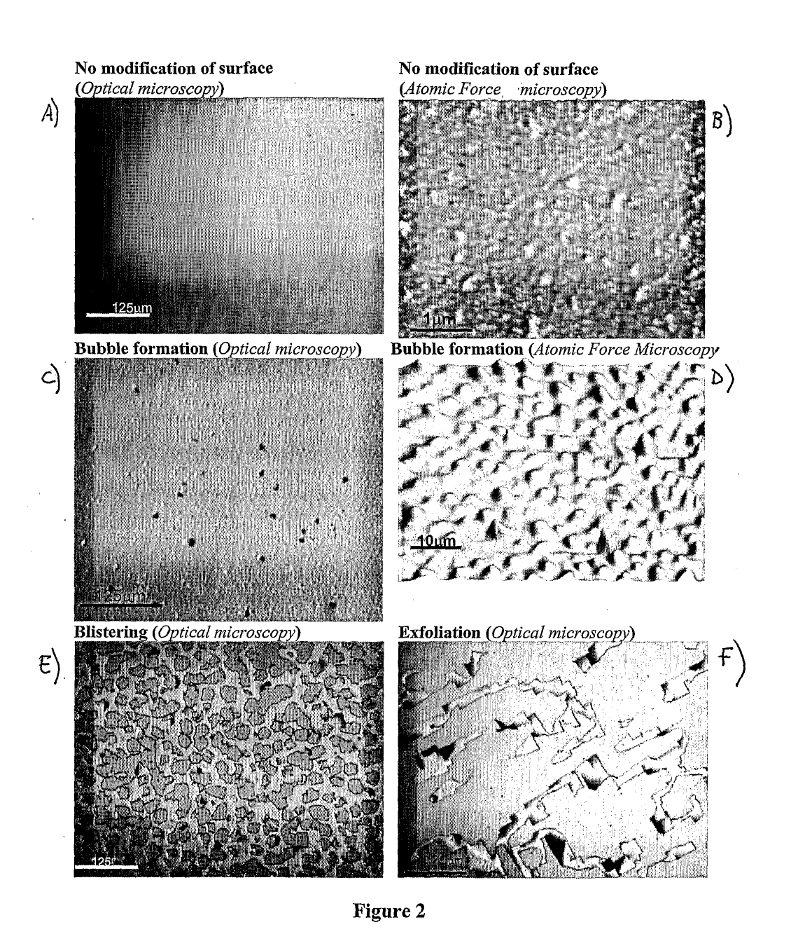

An explanation of different degrees of the physical features that are attendant to exfoliation are described below. The various degrees in hydrogen accumulation are imaged by optical microscopy and/or atomic force microscopy (AFM). Representative images for the following conditions are presented in FIG. 2. FIGS. 2A and 2B illustrate optical and AFM images, respectively, of an unmodified surface.

Bubble formation occurs when a solid is implanted with a large enough ion dose and it is annealed at a high enough temperature to form bubbles. The implanted atoms aggregate inside the solid forming bubbles. As shown in the optical and AFM images in FIGS. 2C and 2D, respectively, the bubble diameters are several microns in diameter. At low enough doses, the bubbles are stable and do not blister.

Blister formation occurs when a solid is implanted with a slightly larger ion dose than what is required for bubble formation. The implanted atoms aggregate inside the solid forming bubbles. The internal pressure inside the bubble is large enough for the bubbles to rupture. This causes delamination of the regions of the material where the bubbles were located, which is referred to herein as a blister. FIG. 2E shows an optical microscopy image of a blistered surface.

Exfoliation occurs when a solid is implanted with an even larger ion dose than what is required for blistering. Blistering is generalized across the surface of the material and then occurs in a collective way in form of layer or film delamination. This referred to as exfoliation and it is the condition necessary for a reproducible layer transfer. FIG. 2F shows an optical microscopy image of an exfoliated surface.

### Monitoring of H-Induced Layer Exfoliation: Signature of Exfoliation

In situ Fourier Transform Infrared spectroscopy (FTIR) is an experimental technique that allows the identification of H-bonded species in the material, as each configuration H adopts has a characteristic absorption peak. By measuring the FTIR spectra of the implanted material during the annealing process it is possible to know what configurations hydrogen atoms adopt inside the solid during the process of exfoliation. In this section, an example of FTIR measurements for the monitoring of H in implanted InP is presented for of finding the signatures of exfoliation that will enable an optimization and quality checking of the implanted wafers. This technique is very general and can be applied to any material that presents FTIR signatures of the implanted species bounded to the constituents of the same.

In the examples of the embodiments of the present invention, the implanted wafer is annealed under a nitrogen atmosphere and the measurements are done all after annealing at a constant temperature. In the specific case of H implanted InP, modes detected in frequencies around 1600 cm⁻¹ correspond to In-H type of vibrations, whereas vibrations around 2300 cm⁻¹ correspond to P-H type of vibrations.

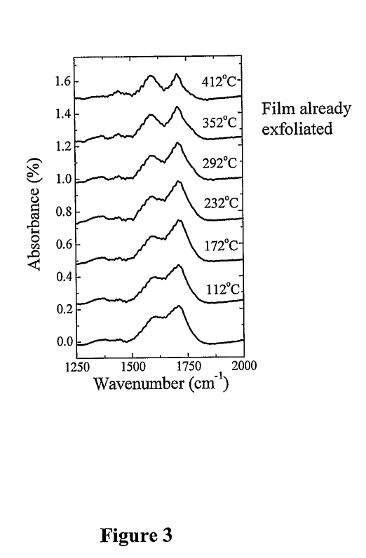

The evolution of In-H vibrations is shown in FIG. 3. The intensity of the peaks does not change substantially after annealing and even after exfoliation. This means that In-H modes are relatively thermally stable and contribute very little to the exfoliation process. On the contrary and as it will be shown below, hydrogen bound to P does contribute to the exfoliation process by passivating internal surfaces. In particular, the specific modes are identified that are the signature of exfoliation.

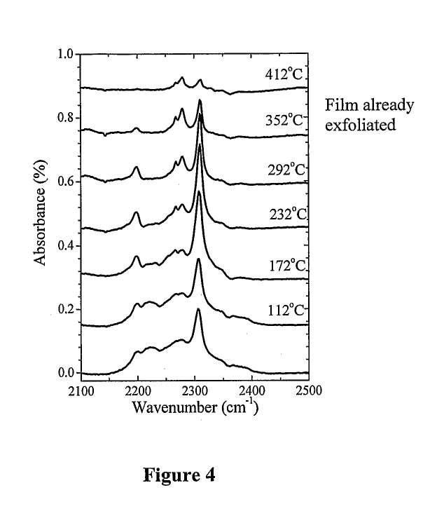

The evolution of P-H modes with subsequent annealing is shown in FIG. 4. The spectrum of the 50° C. sample is composed by two clear peaks at 2306 cm⁻¹ and 2198 cm⁻¹ punctuated by a series of overlapping peaks at intermediate frequencies, specifically at 2217, 2227, 2268, and 2275 cm⁻¹. All of these peaks are associated with P-H modes that will be identified and discussed in the next section with the aid of higher resolution MIT-mode spectra. Here a brief description of the evolution of the P-H during sequential isochronal annealing is presented. There is no change in the spectrum after annealing the sample for 10 min at 112° C. After annealing at 172° C. the overlapping peaks between 2217 and 2227 cm⁻¹ begin to decrease in intensity, disappearing completely after annealing to 292° C. The remaining peaks generally sharpen as the annealing proceeds, while each peak exhibits a unique evolution upon annealing. The intensities of the peaks at 2198, 2268, and 2275 cm⁻¹ decrease, with the peak at 2198 cm⁻¹ nearly disappearing by 352° C., while the peaks at 2268 and 2278 cm⁻¹ are still observed after annealing to 412° C. In addition, the position of the peaks at 2198, 2268, and 2275 cm⁻¹ does not change, while the position of the peak at 2306 cm⁻¹ is shifted to higher energy by 6 cm⁻¹, during which its intensity first increases, reaching a maximum at 232° C., and subsequently decreases significantly by the 412° C. anneal.

By comparison to previous work and as it will be shown in the next section, it is determined that the lower frequency modes correspond to isolated H-passivated defects, whereas the higher frequency modes correspond to hydrogen complexes.

From these measurements several conclusions can be drawn. In the range from 50° C. to 292° C., the simultaneous increase of absorption in the higher wave number modes and decrease of absorption in the lower wave number modes suggests that upon annealing in this temperature range hydrogen bonded to point defects is thermally released from these structures and populates extended defects that it reaches during diffusion. At higher temperatures, the high frequency modes decrease in intensity, indicating that a fraction of the hydrogen forming di-hydrides is debonded. Finally, at temperatures higher than 350° C., InP blisters and most of the mono- and di-hydrides have been decomposed and very little hydrogen is left in the material. Upon hydrogen passivation these defect structures will form the extended defect structures that nucleate micro-cracks that lead to the exfoliation process. Additionally, the hydrogen incorporated in these defect structures can then provide the gas necessary for internal pressure to exfoliate the film.

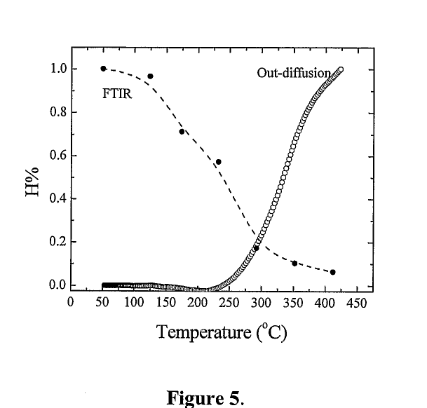

In FIG. 5, the total area under the P-H bands as a function of the annealing temperature is also indicated. The area has been normalized to the total area under the spectra before annealing, and intends to indicate the fraction of hydrogen bonded to P in the material. After annealing at 232° C. about 30% of hydrogen is lost from P-Hₓ modes prior to its loss from the bulk InP material, which is attributed to the formation and trapping of H₂ clusters and molecules. Annealing at higher temperatures, the fraction of bound hydrogen continues to decrease. At 300° C., only 30% of the initially bound hydrogen is still remaining. The proportion of bound hydrogen continues to decrease after annealing at higher temperatures. After annealing at 412° C., InP has blistered and very little hydrogen is left in the material.

To complement the information given by FTIR, the evolution of hydrogen from the InP bulk was measured in a vacuum furnace with a mass spectrometer tuned to mass 2, in order to assess the loss of hydrogen in the material during the annealing cycle. Only after reaching a temperature of 300° C., a significant amount of hydrogen diffusing out of the InP is detected. The diffusion of hydrogen out of the InP is very rapid and ends at 350° C. during exfoliation. This observation is in agreement with the interpretation that hydrogen released from discrete defect structures diffuses in the bulk, where a significant quantity of the mobile hydrogen is captured by extended defects and contributes to internal pressure leading to exfoliation.

A unique FTIR technique is presented that elucidates with more precision the chemical states of hydrogen in H-implanted InP and also the motion of the bonded hydrogen to the exfoliation region. The technique along with the identification of the relevant peaks is used for determining and optimizing the implantation conditions that lead to successful exfoliation. This technique can be applied to any material (eg. GaN, Si, Ge, GaAs, InP and any III-V alloys, diamond, etc.) for the determination and optimization of the conditions for blistering and layer exfoliation. Below, the application of this technique in the case of InP is demonstrated.

MIT-mode FTIR spectroscopy has greater signal-to-noise performance than single pass transmission FTIR spectroscopy, enabled by the enhancement that occurs when the IR beam makes multiple passes through the absorbing medium. In the MIT-FTIR configuration light is introduced through one bevel at the end of the prism sample and makes approximately 57 passes through the sample prior to exiting the opposite bevel and being directed to the detector. As a consequence of being a multi-pass experiment, MIT measurements are more sensitive than single pass transmission, making it easier to resolve weak spectral features. The geometry is denoted MIT since the incident light is able in each reflection to tunnel through the implanted region, which is much thinner than the wavelength of the radiation of interest (see Y. J. Chabal, Internal Transmission Spectroscopy, in Handbook of Vibrational Spectroscopy, p. 1117, (John Wiley and Sons, New York, 2001)). Additionally, by polarizing the IR beam prior to entry into the MIT prism, it is possible to deduce the dipole orientation of the observed modes, thus assisting in the interpretation of the spectra. Moreover, when the implanted species are within a few wavelengths from the external surfaces, interference effects lead to strong intensity modulation for component of the modes as a function of distance from the external surface of the prism. It is therefore possible in some cases to determine spatial information from the spectra. Specifically, the light intensity of each polarization is proportional to the square of the field components and is expressed as follows:

$$\begin{matrix}\begin{matrix}{\vert \vec{{E}_{s}} \vert}^{2} = 4 {E}_{o}^{2} \cdot {\vert \vec{{e}_{y}} \cdot ( exp ( i {k}_{z} \cdot z + Δ ψ ) + exp ( i {k}_{z} \cdot z ) ) \vert}^{2} \\ = 4 {E}_{o}^{2} \cdot {\vert sin θ cos ( {k}_{z} \cdot z + Δψ / 2 ) \vert}^{2} \end{matrix} \\ \begin{matrix}{\vert \vec{{E}_{p}} \vert}^{2} = 4 {E}_{o}^{2} \cdot \vert \vec{{e}_{x}} \cdot ( exp ( i {k}_{z} \cdot z + Δ ψ ) + exp ( i {k}_{z} \cdot z ) ) + \vec{{e}_{z}} \cdot \\ { ( exp ( i {k}_{z} \cdot z + {ψ}_{p} ) + exp ( i {k}_{z} \cdot z ) ) \vert}^{2} \\ = {E}_{o}^{2} \cdot {\vert sin θ cos ( {k}_{z} \cdot z + Δψ / 2 ) \vert}^{2} + {E}_{o}^{2} \cdot {\vert cos θ cos ( {k}_{z} \cdot z \cdot {ψ}_{p} / 2 ) \vert}^{2} \end{matrix} & ( 2 ) \\ {ψ}_{p} / 2 = - arc tan \frac{{n}^{2} \sqrt{{n}^{2} {sin}^{2} θ - 1}}{n cos θ} ; Δ ψ / 2 = π / 2 - {ψ}_{p} / 2 & ( 3 )\end{matrix}$$

where the E corresponds to the electric field, sub-indexes s, p, x, y, z correspond respectively to the components of polarization s and p and parallel to the axes x, y and z. Eₒ is the modulus of the electric field, θ is the incidence angle, ψ the phase change after reflection on one side of the prism and Δψ the shift in the phase change due to the evanescence of the light during reflection.

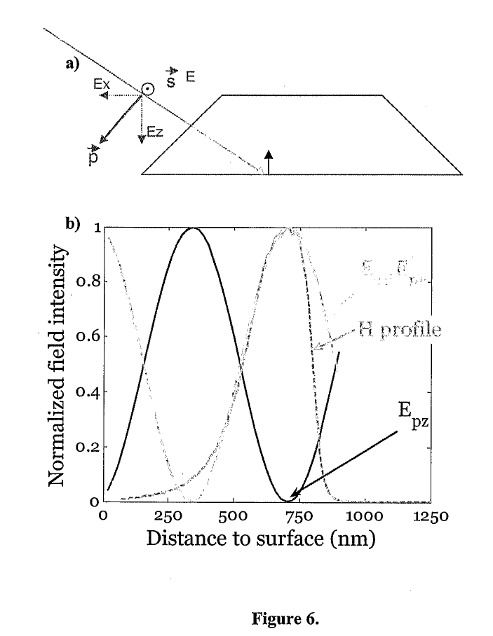

The convention used for the polarization is schematically illustrated in FIG. 6a. Polarization type s corresponds to the component perpendicular to the incidence plane, whereas polarization type p corresponds to the component parallel to the incidence plane. In FIG. 6b, the field intensity of the x-y and z components is plotted as a function of the distance to the interface. The hydrogen distribution in InP after implantation, for the implant conditions used is also shown. The peak of the H-distribution occurs where the z-component of the p polarization is extinguished. As a consequence, the sensitivity to symmetric (100) P-H modes in the peak of the hydrogen implantation, where exfoliation occurs is zero. Interestingly, at that position the y-component of \vec{p}-polarized light and \vec{s}-polarized light are equally intense. Therefore if all bound hydrogen was located at a depth of 700 nm, \vec{s} and \vec{p} peak intensities should be equal. For positions closer to the external surface, the z-component of the \vec{p}-polarized light increases, while the x- and y-components of the \vec{p}- and \vec{s}-polarized light, respectively, decrease. Therefore, the intensity of \vec{p}-polarized light is higher for distances closer to the surface. As a consequence of the different spatial intensity of \vec{p}- and \vec{s}-polarized light, it is possible to obtain spatial information on the bound hydrogen, by comparing the intensity between measurements done at different polarizations.

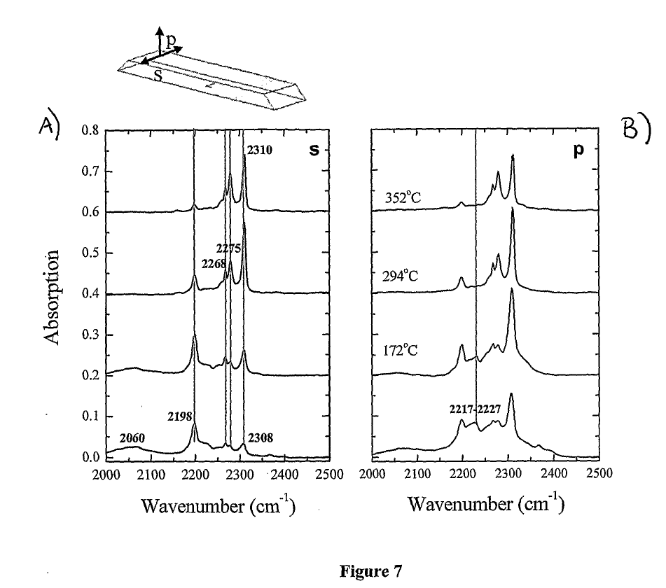

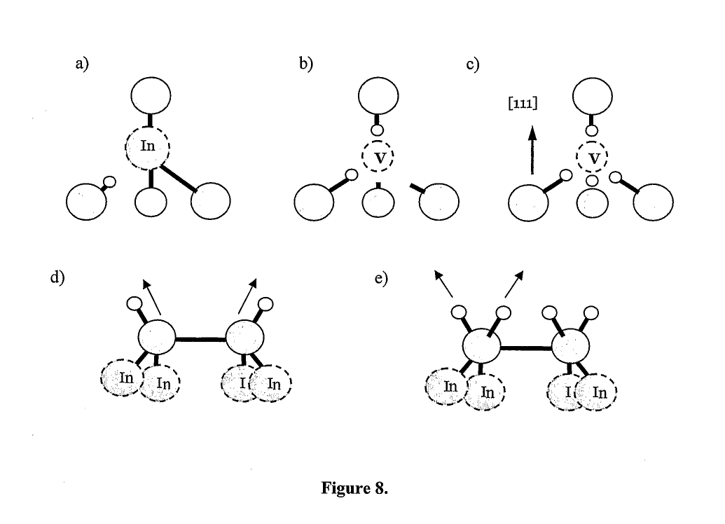

Before entering into detail on the consequences of the extinguished z-component at the H-concentration peak, the origin of the peaks observed in the 2100 to 2300 cm⁻¹ region as measured by MIT-FTIR is discussed. FIGS. 7a and 7b show the absorbance spectra of InP after successive 10 minute isochronal annealing at temperatures ranging from 172° C. to 352° C. The samples were not annealed to higher (exfoliation) temperatures due to limitations in the furnace, and due to the fact that we would have lost nearly all the multi-pass signal due to the imperfect non flat blistered external surface. In comparison to the single-pass transmission-mode measurements, the MIT-mode spectra are more sensitive to defects present in small concentration. For instance, two new absorption peaks appear at 2060 cm⁻¹ and 2250 to 2258 cm⁻¹ in the MIT-mode measurements. While the mode at 2060 cm⁻¹ was not observed in transmission-mode measurements described in the previous section due to the inferior sensitivity of single-pass transmission-mode measurements, the mode from 2250 to 2258 cm⁻¹ could not be detected because it was obscured by two adjacent peaks. After implantation, all of the modes except the modes at 2060 cm⁻¹ and 2198 cm⁻¹ mode exhibit slightly enhanced absorbance in \vec{p}-polarization. Despite the identification of a mode at 2050 cm⁻¹ in previous studies associated with the P-H stretch of a H-passivated (111) surface (see Matthew D. McCluskey, Eugene E. Haller, Semiconductors and Semimetals, vol. 61, pp. 373 (1999)) the disappearance of the mode at 2060 cm⁻¹ between 172 and 294° C. indicates that it is a LVM associated with a discrete hydrogenated defect or distribution of related discrete defects having similar chemical structure, such as a hydrogenated interstitial defects (FIG. 8a). This explanation is consistent with the fact that this mode was never observed in works where H-passivated surfaces were studied. The 2198 cm⁻¹ mode is very close to the LVM at 2206 cm⁻¹ measured by Fischer et al and in perfect agreement with the mode measured by Riede et al. (see D. W. Fischer, M. O. Manasreh, F. Maotus, J. Appl. Phys. 71, 4805 (1992); D. W. Fischer, M. O. Manasreh, D. N. Talwar, F. Maotus, J. Appl. Phys. 73, 78 (1993); D. W. Fischer, M. O. Manasreh, F. Maotus, Semicond. Sci. Technol. 9, 1 (1994); V. Riede, H. Sobotta, H. Neumann, C. Ascheron, C. Neelmeijer, A. Schindler, Phys. Stat. Sol. A 116, K147 (1989)). In these references, this mode is attributed to P-H vibrations of a hydrogen atom localized in a cation vacancy as depicted in FIG. 8b. Eventually, this kind of defect could be filled with more than one hydrogen atom but, as it will be presented in the following paragraph, less than four.

Modes at 2217 and 2227 cm⁻¹ correspond to the stretch modes of H-decorated in vacancies, V_{In}H₄, as drawn in FIG. 8c. In this configuration, the four hydrogen atoms form a tetrahedron and the vibrational dipoles are oriented versus the [111] direction. The mode corresponds to the collective stretching of the four hydrogen atoms. Such vacancies are located in the region prior above the implant end of range where he z-component of \vec{p}-polarized light is roughly three times as intense as the x-component of \vec{s}-polarized light and the y-component of \vec{p}-polarized light. This mode has been nearly annealed out at 294° C., where the peak is still slightly present in the \vec{p} polarized spectrum and completely inexistent in the \vec{s}. The mode at 2268 cm⁻¹ is close to the frequency of 2265 cm⁻¹ attributed in previous work to symmetric stretch modes of H-terminated (100) surfaces with a 2×1 reconstruction. The mode corresponds to a dimer formed by two adjacent atoms, as it is depicted in FIG. 8d. The mode at 2308 cm⁻¹ has been theoretically predicted to be the symmetric stretching vibration of a P-H₂ complex on a <100> InP surface (see FIG. 8e). Experimentally, this mode has been measured at 2317 cm⁻¹ on H-passivated phosphorus rich (001)-(2×1) InP surfaces. The anti-symmetric pair is predicted to be found at 2332 cm⁻¹ with lower intensity than the symmetric mode, and is not detected in our measurements. Such di-hydride complexes could be found both in cation vacancies and at internal surfaces (see ¹C. Asheron, Phys. Stat. Sol. A, 124, 11 (1991); Q. Fu, E. Negro, G. Chen, D. C. Law, C. H. Li, R. F. Hicks, Phys. Rev. B 65, 075318 (2002)). At the same time, this di-hydride dipole could be isotropically oriented, with equal contributions along all axes (x,y,z), because it is not located on a particular surface.

The relative intensity between polarizations can be used in order to obtain spatial information. At the implant conditions selected herein, the maximum hydrogen concentration is located at a distance to the surface corresponding to a position where the z-component of the electric field is zero and therefore \vec{p}- and \vec{s}-polarized spectra should have x- and y-component electric fields with equal intensities. As indicated in FIG. 5b, for distances closer to the external surface, the field intensity of the \vec{s}-polarized spectrum becomes weaker in comparison to the field intensity of the \vec{p}-polarized spectrum. Given the difference in intensity of each peak between the \vec{p}- and \vec{s}-polarized spectra, the approximate location of the modes can be deduced. For instance, in the as-implanted spectra, all of the \vec{p}-polarized peaks have a stronger intensity than the \vec{s}-polarized ones. Only the peak at present 2198 cm⁻¹ has the same intensity in the s and \vec{p}-polarized spectra, which indicates that theses types of defects are mainly located at a distance of ˜700 nm from the surface, where the hydrogen concentration is maximum

As the annealing proceeds, the intensity differences between the two polarizations become less apparent, and at 352° C. they are nearly equivalent. The intensity of the peak at 2308 cm⁻¹ increases with annealing up to 294° C., where it reaches a maximum. The fact that there is a simultaneous increase of the higher wave number LVM's with a decrease of the lower wave number LVM's along with the equilibration of the \vec{p}- and \vec{s}-polarized spectra, suggests that the release of bonded hydrogen in regions between the hydrogen peak concentration and the outer surface due to point defect annealing. This released hydrogen partially captured at the free internal surfaces of voids and/or extended defect structures located at the peak of the H-implant distribution. Indeed, other studies have shown that the formation of clusters of cation vacancies including di-vacancies can be expected at sufficiently high H-implantation doses. Of these defects, the larger defects are predominantly formed in regions of the implanted layer with high damage densities close to the damage peak (see G. Dlubek, C. Ascheron, R. Krause, H. Erhard, D. Klimm, Phys. Stat. Sol. A 106, 81 (1988)). The grouping of hydrogen into the internal surfaces at the peak of the distribution is analogous to a self-gettering process, and it is responsible for the collection of H₂ gas that provides internal pressure and leads blister formation and exfoliation of InP films upon annealing.

Thus, the motion of hydrogen to the end of range implantation region during annealing (just prior to exfoliation) is shown by monitoring of the MIT-FTIR modes at a certain depth. The value of this depth, which determines at what energy the ions should be implanted for this kind of measurement, is given by the value of the refractive index of the material (equations 2 and 3), where the z component of the electric field vanishes. In the case of InP, the signature of the formation of platelets (the precursors of exfoliation) is given by the absorption peak at 2308 cm⁻¹. The identification of this signature can be used for the optimization and quality checking of implant conditions. In other words, the presence of this peak signifies the formation of platelets and indicates that exfoliation can proceed. Thus, the implanted sample can subjected to a MIT-FTIR measurement to determine of this absorption peak is present to determine if the platelets are present and the exfoliation will subsequently occur.

### Exfoliation of InP by Ion Implantation: the Effect of Wafer Temperature During Implantation

The role of temperature during implantation and exfoliation has been suggested in the prior art (see U.S. Pat. No. 5,374,564; Qin-Yi Tong, Ulrich M. Goesele, Adv. Matter, 11, 1409 (1999); L. Di Cioccio, E. Jalaguier, F. Letertre, Phys. Stat. Sol. (a) 202, 509 (2005)). In some publications from Professor Goesele, it has been suggest that wafer temperatures during implantation between 150° C. and 250° C. are necessary for the success of InP hydrogen induced exfoliation and layer transfer. No details on current densities are given, indicating that this restriction in temperature is not implant-current dependent or that the dependency is not known by the authors. However, the present inventors believe that ion implantation at a wafer temperature of 150° C. or higher at least for some semiconductor materials is not desirable, because it leads to an insufficient incorporation of the implanted ions. Considering the dynamics of hydrogen in III-V materials, a set of implant conditions that lead to successful exfoliation of the materials are presented.

Furthermore, U.S. Pat. No. 5,374,564 states that the temperature of the wafer during implantation should being kept below the temperature at which the gas produced by the implanted ions can escape from the semiconductor by diffusion. In contrast, the present inventors believe that the implanted ions diffuse while being still bonded to the substrate atoms and not in the gas form. Moreover, diffusion of hydrogen and/or helium in the material is an activated process, which means that can be described with the following equation:

$$D = {D}_{o} exp ( \frac{- {E}_{a}}{kT} ) \qquad ( 4 )$$

Where Dₒ is a prefactor that depends on the diffusing species and the material, Eₐ is the activation energy and it is related to the bonding energy between the diffusing species and the atoms constituting the material, k is the Boltzmann constant and T is the temperature. This diffusivity temperature dependence means that the value of the diffusivity of the species is never zero and that increases exponentially with temperature. If the value of hydrogen diffusivity for a material is known, then the characteristic time for diffusion of the implant species out of the semiconductor during the implantation process can be calculated. The loss of implanted species at regular wafer temperatures during implantation needs to be taken into account especially in III-V materials. Consequently, a total amount of implanted species in the material should be calculated as a result of the balance between in-flux from implantation and out-flux from diffusion along with the simultaneous buildup of lattice damage and associated internal gas pressure. As the coefficient of diffusion increases exponentially, wafers will need to be implanted at an ion beam current that takes this increase into account. Rough estimates can be made with equation 4, but a more precise dosage can be determined by trying different beam currents at a given temperature and measuring the final profile of the implanted species in the material.

In the sections below, the coefficient of diffusion of hydrogen will be estimated from hydrogen evolution experiments. From the coefficient of diffusion, the implant beam currents needed to avoid insufficient hydrogen incorporation will be also deduced.

### Exfoliation of InP by Hydrogen Implantation

The process consists of the implantation of an effective critical dose of hydrogen atoms, which can be either H⁺ or H₂⁺, in order to create a subsurface damage layer as well as a hydrogen reservoir. A sub-critical dose is any dose which forms a sufficient number of defects for subsequent hydrogenation to be successful but also fails to insert a sufficient quantity of gas species to provide internal pressure inside the material capable of exfoliating a complete layer of the film upon thermal processing. The success of the exfoliation process depends then on the implant parameters, but also on the crystalline structure of InP. InP obtained by different crystal growth techniques, has different impurity and point defect types and concentration that have consequences on the physical, chemical, and mechanical properties of the material. Thus, the crystal growth method impacts the exfoliation dynamics. The total amount of implanted ions contributing to the exfoliation process depends on the structure of InP at the nano-scale because it is this structure that determines the kind of defects where the hydrogen is trapped inside the solid. InP crystals can be obtained by the following techniques: Thermal baffler Liquid Encapsulated Czochralski, tCz, Vertical Gradient Freeze, VGF, Vertical Czochralski, VCZ and Liquid Encapsulated Czochralski, LEC.

Table 1 below shows the minimum implant doses observed to cause exfoliation for InP, for the different growing techniques and different doping.

TABLE 1

| | | Type of crystal | |
|---|---|---|---|
| | Doping | growth | Result |
| 1 | n-type, S doped | Thermal baffler | Exfoliation for doses ≧ |
| | | Liquid Encapsulated | 1e17 H/cm² |
| | | Czochralsky, tCz | |
| 2 | non doped | Thermal baffler | Exfoliation for doses ≧ |
| | | Liquid Encapsulated | 1e17 H/cm² |
| | | Czochralsky, tCz | |
| 3 | Semi-insulating, Fe- | Vertical Gradient | No blistering or |
| | doped | Freeze | exfoliation for doses ≦ |
| | | | 1.5e17 H/cm² |
| 4 | n-type, S doped | Vertical Gradient | Exfoliation for doses ≧ |
| | | Freeze | 1e17 H/cm² |
| 5 | non doped | Vertical Gradient | Exfoliation for doses ≧ |
| | | Freeze | 1e17 H/cm² |
| 6 | n-type, S doped | Vertical | No blistering or |
| | | Czochralski, VCZ | exfoliation for doses ≦ |
| | | | 1.5e17 H/cm² |
| 7 | n-type, S doped | Liquid Encapsulated | Exfoliation for doses ≧ |
| | | Czochralski, LEC | 1.5e17 H/cm² |

Undoped and S-doped InP wafers grown by tCz and VGF techniques can exfoliate for implant doses equal or higher than 10¹⁷H⁺ ions/cm², while p-type or iron doped InP wafers grown by the same technique do not exfoliate for doses up to 1.5×10¹⁷H⁺ ions/cm². For S-doped InP pulled by the LEC technique, it is possible to obtain exfoliation for implant doses equal to or higher than 1.5×10¹⁷H⁺ ions/cm². Finally, S-doped InP wafers obtained by the VCZ technique do not exfoliate for doses up to 1.5×10¹⁷H⁺ ions/cm².

From these experiments, one can deduce that the total dose depends on the implant energies (E) ranging from 25 keV to 400 keV. The lower and higher dose boundaries, for implants realized at a temperature below 100° C., in 10¹⁷H⁺ cm⁻² can be expressed with the following mathematical equation:

$$lower = 3.7 - 24.1 \cdot ( 1 + exp \frac{E + 902}{479.6} )$$

$$higher = 7.5 - 24.5 \cdot ( 1 + exp \frac{E + 658}{671} )$$

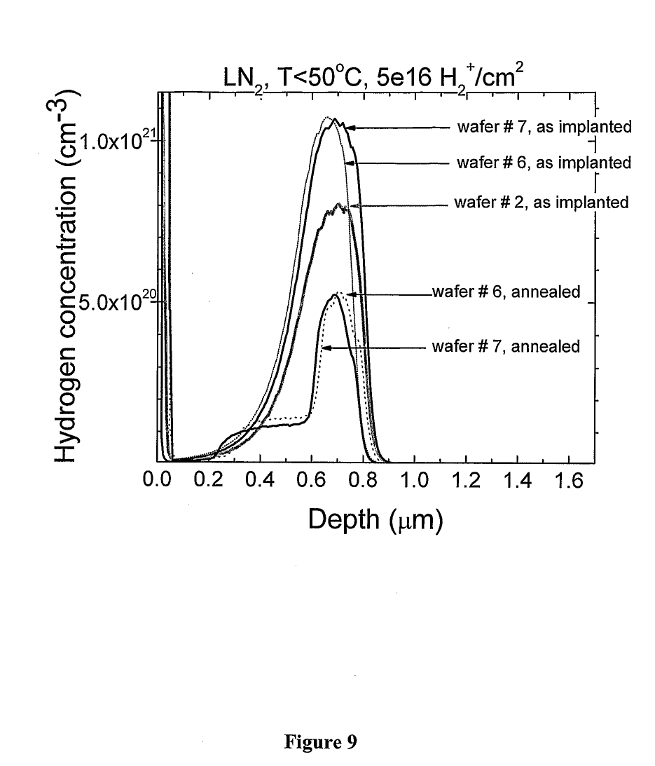

FIG. 9 presents hydrogen concentration profiles obtained by SIMS of three different types of InP wafers, all implanted at the same time with a total dose of 10¹⁷H/cm². The three types of wafers are named in accordance with the table 1, numbers 2, 6, and 7. 2 corresponds to a un-doped InP wafer obtained by tCZ technique, while 6 and 7 are S-doped obtained by the VCZ and LEC technique. While wafer 2 exfoliates after a short anneal at 340° C., samples 6 and 7 do not exfoliate after annealing at 340° C. for more than 4 hours. In FIG. 6, the SIMS profile of wafers 6 and 7 after annealing at 340° C. for 30 min is presented. Hydrogen is distributed in two regions inside the material. However, exfoliation requires the implanted atoms to aggregate in a short space. In wafer numbers 6 and 7 hydrogen stays trapped inside the material, which does not enable the process of bubble formation followed by blistering and exfoliation.

The total amount of hydrogen inside the InP after implantation is the result of a balance between the total implanted dose and the total amount of ions diffused out to the surface. The total amount of ions diffused out of InP depends on the coefficient of diffusion, which is a function of the ion species, the material, and the processing temperature. In particular, the diffusion of coefficient depends exponentially on temperature, meaning that small changes in temperature may increase or decrease the value of the coefficient by several orders of magnitude. Hydrogen-implanted InP was annealed at 10° C./min in a vacuum furnace and the amount of hydrogen out diffused was monitored by Mass Spectrometry. FIG. 5 shows the percentage of hydrogen diffused out of the InP as a function of temperature. After 200° C., hydrogen starts to diffuse out of InP in a time shorter or equal of 1 minute. Because the implantation process typically used for hydrogen-induced exfoliation lasts on the order of one hour, this measurement describes the limiting temperatures during the implantation process. Indeed, the temperature of the wafer has to be controlled so that the implanted ions do not diffuse of the material in significant quantity during the implantation process. From the measurement in FIG. 5 it is estimated that, for typical implant currents up to 200 μA, the wafer temperature has to stay below 150° C. during implantation. For larger currents (shorter implants), it is possible to implant at slightly higher temperature.

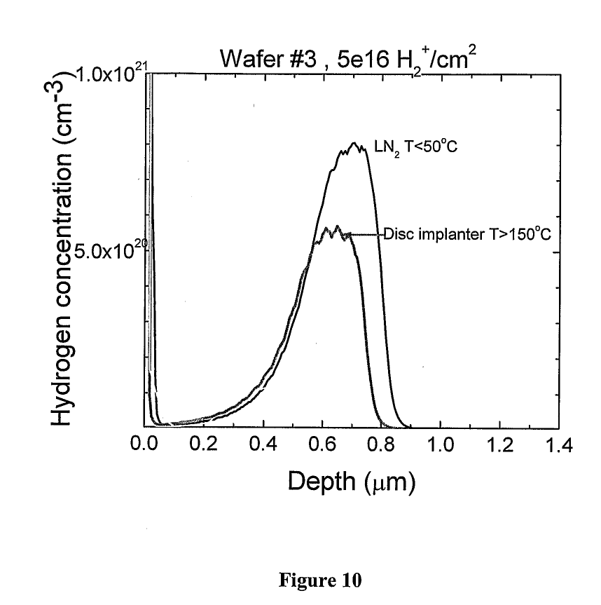

With the purpose of illustrating of the phenomenon of diffusion of hydrogen during implantation, SIMS measurements of InP wafers implanted at different temperatures were done. The results of these measurements are hydrogen concentration profiles and are useful for quantifying the amount of implanted ions remaining inside the material. FIG. 10 compares the hydrogen concentration profile of one InP implanted at a temperature below 50° C. to one InP implanted at a temperature slightly above 150° C. The total dose for both implants is 10¹⁷H/cm². The maximum concentration of the InP implanted below 50° C. is 2.7 times higher than in the InP implanted above slightly 150° C. This is because at temperatures higher than 150° C. hydrogen is mobile inside InP and diffuses out of the solid at the same time that other hydrogen ions are being implanted. This scheme is also valid for heavier ions and is going to be proven in further paragraphs.

The implant parameter space is depicted schematically in Table 2 below.

TABLE 2

| | Estimated | | | |
|---|---|---|---|---|
| Type of Temp | max. | | | |
| control | temperature | Current | Species | Result |
| Liquid nitrogen cooled | <50° C. | 50-125 μA | H₂⁺ | Exfoliation for doses > |
| wafer holder with | | | | 1e17 H/cm² |
| intermediate elastomer | | | | |
| Air cooled substrate | 100° C. | 145 μA for H+ | H⁺ | Exfoliation for doses: |
| holder, wafers | | 105 μA for He+ | He⁺ | ≧1.25e17 H/cm² |
| clamped | | | | ≧1e17 He/cm² |
| | | | | ≧1e17 H/cm² + 2.5e16 |
| | | | | He/cm² |
| Liquid nitrogen cooled | >175° C. | 250 μA | H₂⁺ | Blistering and/or bubble |
| wafer holder with | | | | formation during |
| intermediate elastomer | | | | implantation |
| Non-cooled large | >150° C. | <150 μA in | H₂⁺ | No blistering or |
| volume implanter | | average over the | | exfoliation |
| | | whole disk | | |
| Non-cooled large | 100° C. | <150 μA in | H₂⁺ | Exfoliation for doses ≧ |
| volume implanter, | | average over the | | 1e17 H/cm² |
| interrupted implant | | whole disk | | |
| each 1e16 H₂⁺ | | | | |

Temperature of the wafer is controlled either by active and/or passive cooling to a sufficiently low temperature to control implanted ion diffusion, such as a temperature of below 150° C., such as below 100° C., for example between room temperature and 50° C. The term active cooling means that a cooling medium that actively removes heat from the substrate is in thermal contact with the wafer. The term passive cooling means that the wafer is in thermal contact with a heat sink of a sufficient size to keep the wafer below a maximum temperature during the implantation process.

The following are exemplary methods:
1. Liquid nitrogen cooled particle free wafer holder, with an intermediate elastomer between the wafer and the metal holder: by this active cooling method, it is possible to keep the wafer below 50° C. during the whole implantation process.
2. Air cooled particle free wafer holder: by actively cooling the wafer holder rear side with a constant air flow, it is possible to keep the wafer temperature below 100° C. during the implantation process for implant currents below or equal 1.45 μA/cm².
3. Non-cooled particle free large volume implanter, with a large mass wafer holder (passive cooling): large volume implanter wafer holders are wheels capable of hosting 28 to 40 2″ wafers. When the wafers are well clamped and for currents below 1.50 μA/cm², the wafer reaches a temperature higher than 150° C. during the implantation. This technique can be further improved to reduce the wafer temperature by using an elastomer-coated wafer holder to enhance the thermal coupling of the wafer and large mass wafer holder.
4. Non-cooled particle free large volume implanter, with a large mass wafer holder. Implants interrupted and wafer holder cooled in ambient each 1016 ions/cm²: it is possible to keep the wafer temperature below 150° C. during the whole implantation process. Thus, by interrupting the implant process (i.e., by implanting ions in several different stages separated by wafer cool down time) and/or using a large mass wafer holder and/or by using a material to increase the thermal coupling between the wafer and the holder, passive cooling may be used to cool the wafer to the desired temperature.

The atomic hydrogen reservoir needed for the exfoliation process depends on the total dose, but also on the type of defects in the solid. Indeed, the hydrogen needs to be trapped in the defects for the implantation temperatures but it is important that hydrogen leaves the material at the exfoliation temperature before the surface of InP is decomposed (<350° C.).

### Exfoliation of InP by Helium Ion Implantation

Ion implantation of helium ions at an energy in the range of 25 to 400 keV will enable exfoliation with similar temperature and material restrictions as with hydrogen. The total dose depends on the implant energies (E). The lower and higher dose boundaries, for implants realized at a temperature below 100° C., in 10¹⁷He⁺ cm⁻² can be expressed with the following mathematical equation:

$$lower = 1.2 - 16.2 \cdot ( 1 + exp \frac{E + 205}{74} )$$

$$higher = 1.85 - 23.85 \cdot ( 1 + exp \frac{E + 205}{74} )$$

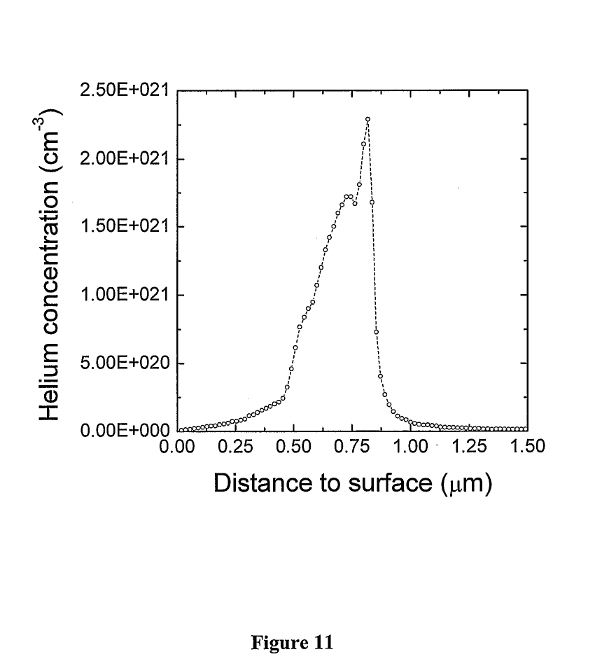

The amount of helium implanted depends on the temperature of the substrate and the ion beam current. The required dose range should be calibrated by SIMS measurements for different semiconductor materials and different ion implanter. FIG. 11 is an example of a SIMS measurement of a sample successfully implanted.

In order to control the substrate temperature, the wafer was mounted on an air-cooled holder. As in the case of implantation with hydrogen ions, the temperature of the wafer during implantation should be kept at a temperature as low as possible, lower than 150° C. for standard implant currents (1.05 μA/cm²).

Using the same substrate cooling conditions, when a current higher than 1.05 μA/cm² is used, InP is heated up to a temperature to about 125° C.-150° C. and blisters during implantation. This is the same phenomenon that also occurs in hydrogen implantation of InP at 150° C., and it indicates that He⁺ implants are also temperature sensitive because of the also high coefficient of diffusion of He in InP. As diffusion is a thermally activated process, diffusion at temperatures below the range 125-150° C. has little influence on the total dose at the currents of between 1 and 1.05 μA/cm². Like in the case of hydrogen ion implantation (H⁺ or H₂⁺), in cases where implant at temperatures close to 150° C. or higher are desired, it would be necessary to increase the total implant current one or two orders of magnitude in order to counteract the exponential increase of coefficient of diffusion of helium. The ratio between the diffusion coefficients at two different temperatures T₁ and T₂ is

$$\frac{{D}_{He} ( {T}_{1} )}{{D}_{He} ( {T}_{2} )} = exp \{ \frac{- {E}_{a}}{KT} ( \frac{1}{{T}_{1}} - \frac{1}{{T}_{2}} ) \} .$$

Supposing Eₐ=0.5 eV, for T₁=50° C. and T₂=150° C. then the ratio between the diffusion coefficient is about 100, which is the factor at least by which the ion beam current should be increased. However, other effects are expected at higher implant currents such as blistering due to interactions between ions in the material during implantation, dynamic enhancement of diffusion of the ion out of the material or an increase of the damage created in the material. (see U. G. Akano, I. V. Mitchell, F. R. Shepherd, Appl. Phys. Lett. 62, 1670 (1993); T. E. Haynes, O. W. Holland, Nucl. Instr. Meth. Phys. Res. B 59/60 1028 (1991)) These phenomena would be also related with a very local heating during implantation than with the overall temperature of the wafer (see S. Tian et al, Nucl. Instr. Meth. Phys. Res. B 112 144 (1996)).

### Exfoliation by Helium/Hydrogen Co-Implantation

Successful layer exfoliation can also be obtained when co-implanting hydrogen (H₂⁺/H⁺) and helium ions (He⁺). The implantation can be carried out with a total dose that depends on the energy, with implanting energies ranging from 40 keV to 200 keV. H⁺ (H₂⁺) and He⁺ implant energies should be selected to ensure that the implant range is the same for both species.

When H⁺ and He⁺ are co-implanted, the implanting energies for the two species can expressed with the following mathematical equation, with ±10% accuracy:

E_{He}·(60−0.11·E_{He})=504+E_{H}·(61−0.06·E_{H}), where E_{He} is the implant energy for He⁺ ions and E_{H} the implant energy for H⁺ ions. The total dose expressed in 10¹⁷ ions/cm² follows the following equation with ±20% accuracy:

$$total dose = 1.5 - 20.5 \cdot ( 1 + exp \frac{E + 205}{74} )$$

When H₂⁺ and He⁺ are co-implanted, then the implanting energies for the two species can expressed with the following mathematical equation, with +10% accuracy:

$${E}_{He} \cdot ( 60 - 0.11 \cdot {E}_{He} ) = 504 + \frac{{E}_{H 2}}{2} \cdot ( 61 - 0.06 \cdot \frac{{E}_{H 2}}{2} ) ,$$

where E_{He} is the implant energy for He⁺ ions and E_{H2} the implant energy for H₂⁺ ions, which count for two implanted atoms. The total dose expressed in 10¹⁷ atoms/cm² follows the following equation with ±20% accuracy:

$$total dose = 1.5 - 20.5 \cdot ( 1 + exp \frac{E + 205}{74} )$$

### Estimation of Coefficient of Diffusion of Hydrogen and Consequences to the Ion Beam Current Required

With some basic assumption such as the time (τ) necessary for hydrogen to diffuse a certain length λ, the coefficient of diffusion of hydrogen (D_{H}) can be estimated with the following equation:

$${D}_{H} = \frac{{λ}^{2}}{τ} \qquad ( 5 )$$

Also, by supposing a certain value for the activation energy—which should be within 0.5 and 1 eV—one can estimate the temperature dependence. Then, using the same equation 5, the time required for the implanted species to diffuse out of the material can be calculated. For efficient incorporation of the implanted species, it is necessary for the time required to diffuse out to be at least lower than half the implantation time. To optimize process economics, the characteristic diffusion time should be less than half of the time required to introduce the exfoliating species by ion implantation.

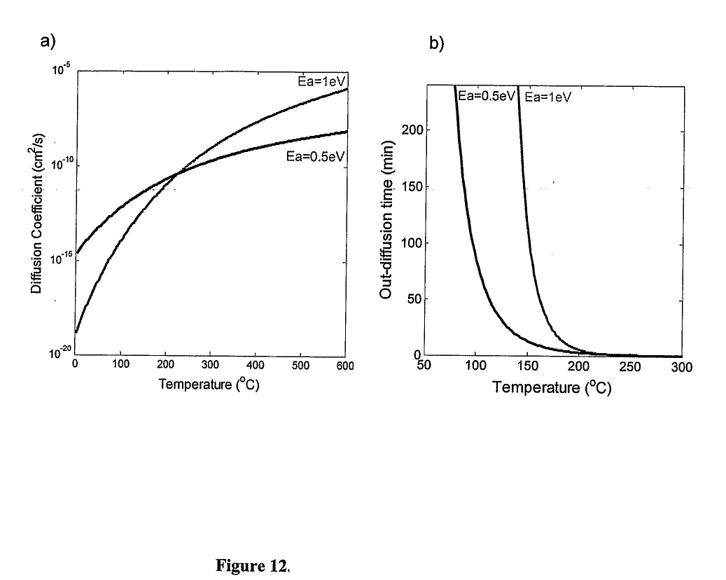

From the hydrogen thermal evolution measurements (see FIG. 5), one can estimate D_{H} at 225° C. Hydrogen is located at about 1=650 nm far from the surface. Overestimating the diffusion time to the surface to about 1 min, we get a coefficient of diffusion D_{H} of 4×10¹¹ cm²/s. FIG. 12a shows what would be the values of D as a function of temperature assuming reasonable boundary activation energies of 0.5 and 1 eV. The out-diffusion time is calculated in FIG. 12b. The exponential decrease and relative small values of the out-diffusion time at temperatures higher than 100°-150° C. is representative of the importance of the wafer temperature during implantation. This principle is applied to all materials, but it is specially important for InP and GaAs related materials, due to the high coefficient of diffusion of small atoms such as hydrogen and helium.

### Exfoliation of GaAs: the Role of Wafer Temperature During Implantation

The role of temperature during implantation and exfoliation has also been suggested in the prior art (see Qin-Yi Tong, Ulrich M. Goesele, Adv. Matter, 11, 1409 (1999)). In the publications, it has been claimed that wafer temperatures during implantation between 160° C. and 250° C. are necessary for the success of GaAs hydrogen induced exfoliation and layer transfer. No details on current densities are given, indicating that the dependency is not known by the authors. The present inventors have performed experiments and conclude that implanting GaAs at temperatures between 160° C. and 250° C. does not lead to reliable exfoliation during a post-implant annealing.

It is believed that as in the case of InP, the implanted ions diffuse while being still bonded to the substrate atoms and not in the gas form. Moreover, diffusion of hydrogen and/or helium in the material is an activated process, which means that can be described with the following equation:

$$D = {D}_{o} exp ( \frac{- {E}_{a}}{kT} ) \qquad ( 4 )$$

Where Dₒ is a prefactor that depends on the diffusing species and the material, Eₐ is the activation energy and it is related to the bonding energy between the diffusing species and the atoms constituting the material, k is the Boltzmann constant and T is the temperature.

What this equation means is that the value of the diffusivity of the species is never zero and that increases exponentially with temperature. If the value of hydrogen diffusivity for a material is known, then the characteristic time for diffusion of the implant species out of the semiconductor during the implantation process can be calculated. As it will be shown herein, the loss of implanted species at regular wafer temperatures during implantation needs to be taken into account especially in III-V materials. Consequently, it is necessary to calculate total amount of implanted species in the material as a result of the balance between in-flux from implantation and out-flux from diffusion along with the simultaneous buildup of lattice damage and associated internal gas pressure. As the coefficient of diffusion increases exponentially, wafers will need to be implanted at an ion beam current that takes this increase into account. Estimates can be done with equation 4, but a more precise dosage can be estimated by trying different beam currents at a given temperature and measuring the final profile of the implanted species in the material.

### Exfoliation of GaAs by Ion Implantation

The helium implantation process includes the implantation of an effective critical dose of He⁺ in order to create a subsurface damage layer as well as a helium reservoir for the layer exfoliation. For the success of the process it is believed that the temperature of the wafer should not exceed 150° C. during implantation. The total dose depends on the implant energies (E), which may vary from 25 keV to 400 keV. The lower and higher dose boundaries, for implants realized at a temperature below 150° C., in 10¹⁷He⁺ cm⁻² can be expressed with the following mathematical equation:

$$lower = 1.2 - 19.4 \cdot ( 1 + exp \frac{E + 244}{82} )$$

$$higher = 1.2 - 28.6 \cdot ( 1 + exp \frac{E + 244}{82} )$$

If the implanted species used are H₂⁺ ions, then the total dose also depends on the implant energies (E) ranging from 25 keV to 200 keV. The lower and higher dose boundaries in 10¹⁷H₂⁺cm⁻² can be expressed with the following mathematical equation:

$$lower = \frac{1}{2} \cdot ( 3.7 - 24.1 \cdot ( 1 + exp \frac{\frac{E}{2} + 902}{479.6} ) )$$

$$higher = \frac{1}{2} \cdot ( 7.5 - 24.5 \cdot ( 1 + exp \frac{\frac{E}{2} + 658}{671} ) )$$

As it was mentioned in the case of InP, diffusion of implanted species has little influence on the total dose at the currents of between 1 and 1.05 μA/cm² for implantation temperatures below 150° C., while at temperatures close to 150° C. and higher it should be necessary to increase the total current between 1 and 2 orders of magnitude according to the exponential increase of the coefficient of diffusion. It has been observed that ion implantation at very large currents can also enhance other phenomena such as creation of more damage to the material and diffusion of the ion out of the material. This phenomenon has more to do with a very local heating during implantation than with the overall temperature of the wafer.

While particular embodiments of the present invention have been shown and described, it will be obvious to those skilled in the art that changes and modifications may be made without departing from the invention in its broader aspects and, therefore, the appended claims are to encompass within their scope all such changes and modifications as fall within the true spirit and scope of this invention. All patents, published applications and articles mentioned herein are incorporated by reference in their entirety.

1. A method of making a semiconductor thin film bonded to a handle substrate, comprising:
implanting a semiconductor substrate with a light ion species while cooling the semiconductor substrate;
bonding the implanted semiconductor substrate to the handle substrate to form a bonded structure; and
annealing the bonded structure, such that the semiconductor thin film is transferred from the semiconductor substrate to the handle substrate.

2. The method of claim 1, wherein the step of cooling the semiconductor substrate comprises cooling the semiconductor substrate to a temperature below 150° C.

3. The method of claim 2, wherein the step of cooling the semiconductor substrate comprises passively cooling the semiconductor substrate.

4. The method of claim 2, wherein the step of cooling the semiconductor substrate comprises actively cooling the semiconductor substrate.

5. The method of claim 2, wherein the semiconductor substrate comprises a compound semiconductor substrate.

6. The method of claim 5, wherein the semiconductor substrate comprises a III-V semiconductor substrate.

7. The method of claim 6, wherein the semiconductor substrate comprises an InP or a GaAs semiconductor substrate.

8. The method of claim 2, wherein the step of implanting is conducted in separate stages to allow the semiconductor substrate to cool down between the separate stages to remain below 150 C during an entire implantation process.

9. The method of claim 2, further comprising mounting the semiconductor substrate in a substrate holder in an ion implanter, such that the semiconductor substrate is maintained in close contact with the substrate holder through a thermally conductive elastic material.

10. The method of claim 2, wherein the step of cooling the semiconductor substrate comprises cooling the semiconductor substrate to a temperature below 100° C.

11. The method of claim 1, wherein the step of cooling the semiconductor substrate comprises actively cooling the semiconductor substrate.

12. The method of claim 11, wherein the step of actively cooling the semiconductor substrate comprises mounting the semiconductor substrate in a substrate holder in an ion implanter and actively cooling the substrate holder with a cooling medium.

13. The method of claim 12, wherein the step of actively cooling the substrate holder comprises passing the cooling medium through the substrate holder.

14. A method of making a III-V compound semiconductor thin film bonded to a handle substrate, comprising:
implanting a III-V compound semiconductor substrate with a light ion implantation species;
bonding the implanted III-V compound semiconductor substrate to the handle substrate to form a bonded structure; and
annealing the bonded structure, such that the III-V compound semiconductor thin film is transferred from the III-V compound semiconductor substrate to the handle substrate;
wherein conditions for the step of implanting are selected from one of the following groups of conditions (a), (b), (c), (d), (e), (f) or (g):
(a) the III-V compound semiconductor substrate comprises an InP substrate, the implantation species comprise H⁺ ions, implant energies (E) range from 25 keV to 400 keV and H⁺ ion implantation dose, in units of 10¹⁷H⁺ cm⁻², ranges between following lower and higher bounds:
$$lower = 3.7 - 24.1 \cdot ( 1 + exp \frac{E + 902}{479.6} )$$
$$higher = 7.5 - 24.5 \cdot ( 1 + exp \frac{E + 658}{671} )$$
(b) the III-V compound semiconductor substrate comprises an InP substrate, the implantation species comprise H₂⁺ ions, implant energies (E) range from 25 keV to 400 keV and H₂⁺ ion implantation dose, in units of 10¹⁷H₂⁺ cm⁻², ranges between following lower and higher bounds:
$$lower = \frac{1}{2} \cdot ( 3.7 - 24.1 \cdot ( 1 + exp \frac{\frac{E}{2} + 902}{479.6} ) )$$
$$higher = \frac{1}{2} \cdot ( 7.5 - 24.5 \cdot ( 1 + exp \frac{\frac{E}{2} + 658}{671} ) )$$
(c) the III-V compound semiconductor substrate comprises an InP substrate, the implantation species comprise He⁺ ions, implant energies (E) range from 25 keV to 400 keV and He⁺ ion implantation dose, in units of 10¹⁷He⁺ cm⁻², ranges between following lower and higher bounds:
$$lower = 1.2 - 16.2 \cdot ( 1 + exp \frac{E + 205}{74} )$$
$$higher = 1.85 - 23.85 \cdot ( 1 + exp \frac{E + 205}{74} )$$
(d) the III-V compound semiconductor substrate comprises an InP substrate, the implantation species comprise H⁺ ions and He⁺ ions, implant energies (E) range from 40 keV to 200 keV such that an implant range in the substrate is the same for both species and vary by 10 percent or less from the following equation E_{He}·(60−0.11·E_{He})=504+E_{H}·(61−0.06·E_{H}), where E_{He} is an implant energy for He⁺ ions and E_{H} the implant energy for H⁺ ions, and a total ion implantation dose, in units of 10¹⁷ ions/cm² is within 20 percent or less of the following value:
$$total dose = 1.5 - 20.5 \cdot ( 1 + exp \frac{E + 205}{74} )$$
(e) the III-V compound semiconductor substrate comprises an InP substrate, the implantation species comprise H₂⁺ ions and He⁺ ions, implant energies (E) range from 40 keV to 200 keV such that an implant range in the substrate is the same for both species and vary by 10 percent or less from the following equation
E_{He}·(60−0.11·E_{He})=504+E_{H2}/2(61−0.06·E_{H2}/2), where E_{He} is the implant energy for He⁺ ions and E_{H2} the implant energy for H₂⁺ ions, and a total ion implantation dose, in units of 10¹⁷ ions/cm² is within 20 percent or less of the following value:
$$total dose = 1.5 - 20.5 \cdot ( 1 + exp \frac{E + 205}{74} )$$
(f) The III-V compound semiconductor substrate comprises a GaAs substrate, the implantation species comprise He⁺ ions, implant energies (E) range from 25 keV to 400 keV and He⁺ ion implantation dose, in units of 10¹⁷He⁺cm⁻², ranges between following lower and higher bounds:
$$lower = 1.2 - 19.4 \cdot ( 1 + exp \frac{E + 244}{82} )$$
$$higher = 1.2 - 28.6 \cdot ( 1 + exp \frac{E + 244}{82} ) ; or$$
(g) the III-V compound semiconductor substrate comprises a GaAs substrate, the implantation species comprise H₂⁺ ions, implant energies (E) range from 25 keV to 200 keV and H₂⁺ ion implantation dose, in units of 10¹⁷H₂⁺cm⁻², ranges between the following lower and higher bounds:
$$lower = \frac{1}{2} \cdot ( 3.7 - 24.1 \cdot ( 1 + exp \frac{\frac{E}{2} + 902}{479.6} ) )$$
$$higher = \frac{1}{2} \cdot ( 7.5 - 24.5 \cdot ( 1 + exp \frac{\frac{E}{2} + 658}{671} ) ) .$$

15. The method of claim 14, wherein conditions for the step of implanting are selected from conditions of group (a).

16. The method of claim 14, wherein conditions for the step of implanting are selected from conditions of group (b).

17. The method of claim 14, wherein conditions for the step of implanting are selected from conditions of group (c).

18. The method of claim 14, wherein conditions for the step of implanting are selected from conditions of group (d).

19. The method of claim 14, wherein conditions for the step of implanting are selected from conditions of group (e).

20. The method of claim 14, wherein conditions for the step of implanting are selected from conditions of group (f).

21. The method of claim 14, wherein conditions for the step of implanting are selected from conditions of group (g).

22. The method of claim 15, wherein the ion implantation dose comprises between 1×10¹⁷H⁺/cm² and 1.5×10¹⁷H⁺/cm², the implant energy is between 60 and 120 keV and a beam current is kept below 150 μA/cm².

23. The method of claim 16, wherein the ion implantation dose comprises between 5×10¹⁶H₂⁺/cm² and 7.5×10¹⁶H₂⁺/cm², the implant energy is between 120 and 240 keV, and a beam current is kept below 150 μA/cm².

24. The method of claim 17, wherein the ion implantation dose comprises between 1×10¹⁷He⁺/cm² and 1.5×1017He⁺/cm², the implant energy is between 80 and 140 keV and a beam current is kept below 120 μA/cm².

25. A method of making a semiconductor thin film bonded to a handle substrate, comprising:
implanting a first semiconductor substrate with a light ion implantation species;
performing a Fourier Transform Infrared Spectroscopy (FTIR) measurement on the first semiconductor substrate to monitor at least one mode responsible for the semiconductor thin film exfoliation;
bonding the implanted first semiconductor substrate to the handle substrate to form a bonded structure; and
annealing the bonded structure, such that the semiconductor thin film is transferred from the first semiconductor substrate to the handle substrate.

26. The method of claim 25, wherein the step of performing the FTIR measurement is performed in-situ during the step of implanting.

27. The method of claim 25, further comprising determining a quality of the transferred layer based on the step of performing the FTIR measurement.

28. The method of claim 25, further comprising at least one of optimizing or controlling implantation parameters during a subsequent step of implanting a second semiconductor substrate based on the step of monitoring the at least one mode responsible for the semiconductor thin film exfoliation from the first semiconductor substrate, bonding the second semiconductor substrate to a second handle substrate and exfoliating a semiconductor thin film from the second semiconductor substrate.

29. The method of claim 25, wherein the first semiconductor substrate comprises an InP substrate, the light ion species comprise hydrogen ions, and further comprising assessing configurations of the implanted hydrogen in the InP substrate by detecting vibrational modes by FTIR between 2198 and 2315 cm⁻¹.

30. The method of claim 25, wherein the first semiconductor substrate comprises an InP substrate, the light ion species comprise hydrogen ions and further comprising using FTIR to in-situ monitor the bonded structure during a step of exfoliation of the semiconductor thin film to detect an increase of modes at 2306 to 2010 cm⁻¹.
